(19) United States
(12) Patent Application Publication
(10) Pub. No.: US 2012/0146198 A1
(43) Pub. Date: Jun. 14, 2012

(54) INTEGRATED CIRCUITS AND FABRICATION PROCESS THEREOF

(76) Inventors: Haibin YANG, Shanghai (CN); Yongbin YUAN, Shanghai (CN)

(21) Appl. No.: 12/969,206

(22) Filed: Dec. 15, 2010

(30) Foreign Application Priority Data
Dec. 8, 2010 (CN) 201010578299.0

(51) Int. Cl. H01L 23/50; H03K 3/01; H01L 21/768

(52) U.S. Cl. 257/664; 438/618; 327/534; 257/E23.079; 257/E21.575

(57) ABSTRACT

An integrated circuit includes a conductive pad and a substrate. The conductive pad is used to transfer a first signal. The substrate blocks a second signal from a first region of the substrate to the conductive pad. A second region of the substrate insulates a third region of the substrate from the first region. The first and third regions include a first type of semiconductor and the second region includes a second type of semiconductor. In addition, a first shadow obtained by perpendicularly projecting the third region onto a surface of the substrate overlaps with a second shadow obtained by perpendicularly projecting the conductive pad onto the surface.

### RELATED APPLICATION

This application claims priority of Patent Application No. 201010578299.0, titled “INTEGRATED CIRCUITS AND FABRICATION PROCESS THEREOF”, filed on Dec. 8, 2010, with the State Intellectual Property Office of the People's Republic of China.

### BACKGROUND

Integrated circuits (ICs) usually include substrates that are made of semiconductor. An IC can be fabricated based on a semiconductor substrate by steps of photomasking, diffusion, oxidation, epitaxial growth, deposition, etc. FIG. 1A illustrates part of a cross-sectional diagram of a wafer 100 for a conventional IC. FIG. 1B illustrates part of an equivalent circuit diagram 100′ of an IC fabricated based on the wafer 100. As shown in FIG. 1B, the metal pad 102 is coupled to a circuit 120 and used to transfer a signal for the circuit 120. However, as shown in FIG. 1A, the metal pad 102 is insulated from the semiconductor substrate 104 by an insulation layer 106, e.g., a silicon dioxide (SiO₂) layer, and therefore an equivalent capacitor 110 shown in FIG. 1B is formed. Consequently, noises may be transferred from the semiconductor substrate 104 to the metal pad 102 via the equivalent capacitor 110, which interferes with the signal at the metal pad 102.

### SUMMARY

In one embodiment, an integrated circuit includes a conductive pad and a substrate. The conductive pad is used to transfer a first signal. The substrate can block a second signal from a first region of the substrate to the conductive pad. In one such embodiment, a second region of the substrate insulates a third region of the substrate from the first region. The first and third regions include a first type of semiconductor and the second region includes a second type of semiconductor. In addition, a first shadow obtained by perpendicularly projecting the third region onto a surface of the substrate overlaps with a second shadow obtained by perpendicularly projecting the conductive pad onto the surface.

### BRIEF DESCRIPTION OF THE DRAWINGS

Features and advantages of embodiments of the claimed subject matter will become apparent as the following detailed description proceeds, and upon reference to the drawings, wherein like numerals depict like parts, and in which:

FIG. 1A illustrates part of a cross-sectional diagram of a wafer for an integrated circuit, in accordance with the prior art.

FIG. 1B illustrates part of an equivalent circuit diagram of an integrated circuit, in accordance with the prior art.

FIG. 2A illustrates part of a cross-sectional diagram of an example of a wafer for an integrated circuit, in accordance with one embodiment of the present invention.

FIG. 2B illustrates a diagram of an example of an equivalent circuit formed by the wafer in FIG. 2A, in accordance with one embodiment of the present invention.

FIG. 3 illustrates a block diagram of an example of an electronic system, in accordance with one embodiment of the present invention.

FIG. 4 illustrates a flowchart of examples of operations performed by an integrated circuit, in accordance with one embodiment of the present invention.

FIG. 5A and FIG. 5B illustrate examples of fabrication steps for an integrated circuit, in accordance with one embodiment of the present invention.

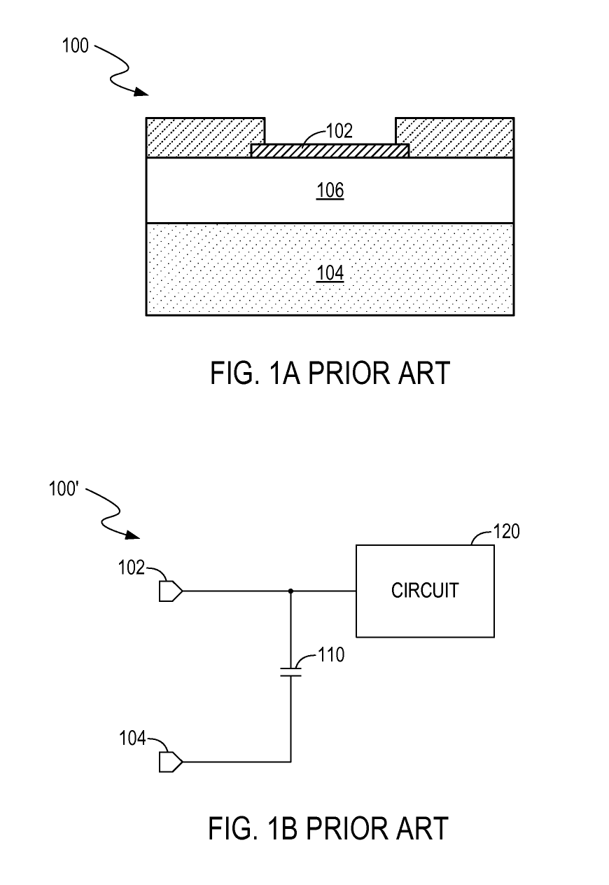

### DETAILED DESCRIPTION

Reference will now be made in detail to the embodiments of the present invention. While the invention will be described in conjunction with these embodiments, it will be understood that they are not intended to limit the invention to these embodiments. On the contrary, the invention is intended to cover alternatives, modifications and equivalents, which may be included within the spirit and scope of the invention as defined by the appended claims.

Furthermore, in the following detailed description of the present invention, numerous specific details are set forth in order to provide a thorough understanding of the present invention. However, it will be recognized by one of ordinary skill in the art that the present invention may be practiced without these specific details. In other instances, well known methods, procedures, components, and circuits have not been described in detail as not to unnecessarily obscure aspects of the present invention.

Some portions of the detailed descriptions that follow are presented in terms of procedures, logic blocks, processing, and other symbolic representations of operations for fabricating semiconductor devices. These descriptions and representations are the means used by those skilled in the art of semiconductor device fabrication to most effectively convey the substance of their work to others skilled in the art. In the present application, a procedure, logic block, process, or the like, is conceived to be a self-consistent sequence of steps or instructions leading to a desired result. The steps are those requiring physical manipulations of physical quantities. It should be borne in mind, however, that all of these and similar terms are to be associated with the appropriate physical quantities and are merely convenient labels applied to these quantities. Unless specifically stated otherwise as apparent from the following discussions, it is appreciated that throughout the present application, discussions utilizing terms such as “forming,” “growing,” “depositing,” “etching” or the like, refer to actions and processes of semiconductor device fabrication.

Furthermore, other fabrication processes and steps may be performed along with the processes and steps discussed herein; that is, there may be a number of processes and steps before, in between and/or after the steps shown and described herein. Importantly, embodiments of the present invention can be implemented in conjunction with these other processes and steps without significantly perturbing them. Generally speaking, the various embodiments of the present invention can replace portions of a conventional process without significantly affecting peripheral processes and steps.

It is understood that the figures are not drawn to scale, and only portions of the structures depicted, as well as the various layers that form those structures, may be shown.

In one embodiment, the present invention provides an integrated circuit fabricated based on a semiconductor substrate, e.g., p-type substrate or n-type substrate, and a method for fabricating the integrated circuit. The integrated circuit includes one or more conductive pads, e.g., golden pads, aluminum pads, etc., deposited on a wafer. The semiconductor substrate in the wafer can include three regions doped with p-type or n-type impurities. Advantageously, such semiconductor substrate can block interfering signals, e.g., noises, from the semiconductor substrate to the conductive pads.

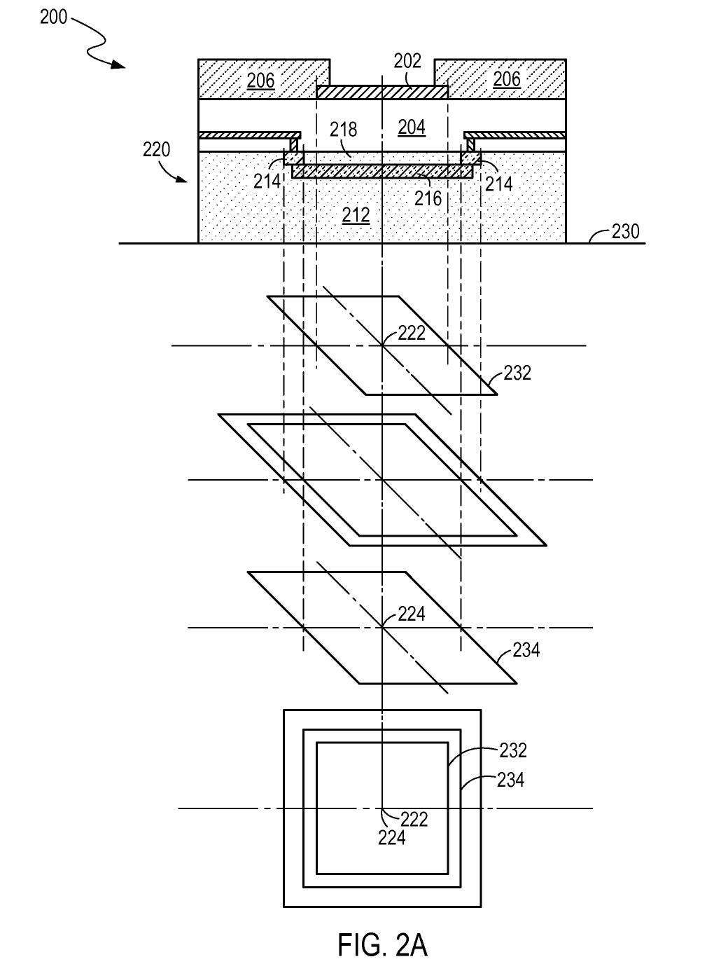

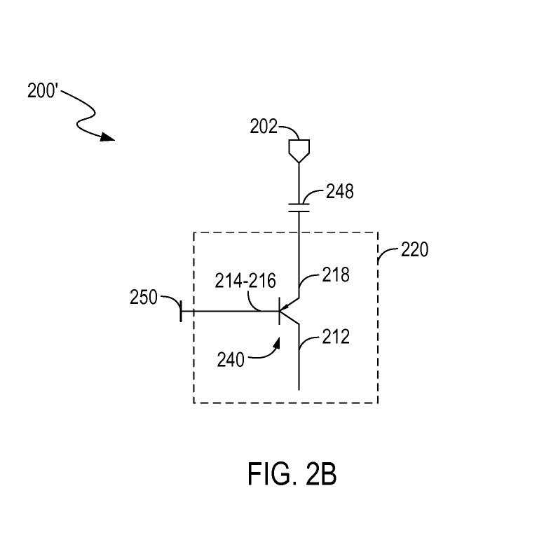

FIG. 2A illustrates part of a cross-sectional diagram of an example of a wafer 200, e.g., a silicon wafer, for an integrated circuit, in accordance with one embodiment of the present invention. As shown in FIG. 2A, the wafer 200 includes a passivation layer 206, a conductive pad 202, an insulation region 204, and a semiconductor substrate 220.

The passivation layer 206, e.g., a silicon nitride (Si₃N₄) layer, passivates a surface of the wafer 200 to protect the wafer 200. The conductive pad 202 can transfer a signal between the integrated circuit and an external circuit outside the integrated circuit. For example, the conductive pad 202 is coupled to an external pin of the integrated circuit via a gold wire. A signal can be transferred via the conductive pad 202, the gold wire, and the external pin. The conductive pad 202 can be a metal pad, e.g., an aluminum pad, a gold pad, etc. The insulation region 204, e.g., a silicon dioxide (SiO₂) region, is used to insulate a conductive layer, e.g., where the conductive pad 202 is deposited, from the semiconductor substrate 220.

The semiconductor substrate 220 includes a bottom region 212, a top region 218, and a middle region that includes a well 214 and a buried-layer 216 (hereinafter, middle region 214-216). The middle region 214-216 insulates the top region 218 from the bottom region 212. The regions 212 and 218 include a first type of semiconductor. The middle region 214-216 includes a second type of semiconductor. More specifically, in one embodiment, the bottom region 212 includes p-type semiconductor and can be referred to as a p-type substrate. The top region 218 also includes p-type semiconductor. The middle region 214-216 includes an n-type doped well (n-well) 214 and an n-type heavily doped (n+) buried-layer 216, in one embodiment. A concentration of n-type impurities, e.g., pentavalent atoms, in the n+ buried-layer 216 is greater than the concentration of n-type impurities in the n-well 214.

The p-type semiconductor can be obtained by adding trivalent atoms, e.g., boron (B) atoms, aluminum (Al) atoms, etc., to single-crystal silicon, such that the p-type semiconductor includes free holes. The n-type semiconductor can be obtained by adding pentavalent atoms, e.g., phosphorus (P) atoms, arsenic (As) atoms, etc., to single-crystal silicon, such that the n-type semiconductor includes free electrons.

Thus, the top region 218, the middle region 214-216, and the bottom region 212 form a PNP bipolar junction transistor (BJT). For example, an equivalent PNP BJT 240 is shown in FIG. 2B. FIG. 2B illustrates a diagram of an equivalent circuit 200′ formed by the substrate 220, the insulation region 204 and the conductive pad 202 in FIG. 2A, in accordance with one embodiment of the present invention. Elements that are labeled the same as in FIG. 2A have similar functions. As shown in FIG. 2B, an equivalent capacitor 248 can be formed between the conductive pad 202 and the PNP BJT 240 because of the conductive pad 202 and the top region 218. The PNP BJT 240 can be formed by the top region 218, the middle region 214-216, and the bottom region 212. In the example of FIG. 2B, the top region 218 constitutes an emitter of the PNP BJT 240, the middle region 214-216 constitutes a base of the PNP BJT 240, and the bottom region 212 constitutes a collector of the PNP BJT 240. In one embodiment, the middle region 214-216 receives a power voltage 250, such that the middle region 214-216 has a substantially constant voltage level V_{B} that is higher than a voltage level V_{E} at the top region 218 and higher than a voltage level V_{C} at the bottom region 212. In one embodiment, the power voltage 250 includes, but is not limited to, a positive direct-current (DC) power voltage V_{DD}. As such, the PNP BJT 240 operates in a cut-off state. In one embodiment, interfering signals, e.g., noises, may exist in the bottom region 212. Advantageously, since the PNP BJT 240 operates in the cut-off state, the interfering signals are blocked by the semiconductor substrate 220 from the bottom region 212 to the conductive pad 202.

Returning to FIG. 2A, a projection shadow obtained by perpendicularly projecting the top region 218 onto a bottom surface 230 of the semiconductor substrate 220 (or a bottom surface of the wafer 200) overlaps with a projection shadow obtained by perpendicularly projecting the conductive pad 202 onto the bottom surface 230 of the semiconductor substrate 220 (or the bottom surface of the wafer 200). For example, as shown in FIG. 2A, a projection shadow 232, e.g., a planar shadow, is obtained by projecting the conductive pad 202 onto the bottom surface 230 perpendicularly, and a projection shadow 234, e.g., a planar shadow, is obtained by projecting the top region 218 onto the bottom surface 230 perpendicularly. The projection shadow 234 representing the top region 218 overlaps with the projection shadow 232 representing the conductive pad 202.

In the example of FIG. 2A, a center 224 of the projection shadow 234 overlaps with a center 222 of the projection shadow 232. In addition, the projection shadow 234 is larger than and covers the projection shadow 232. Thus, the semiconductor substrate 220 has an improved noise isolation function in blocking signals from the bottom region 212 to the conductive pad 202. In one embodiment, the larger the projection shadow 234 than the projection shadow 232, the stronger the noise isolation is. Although the center 224 of the projection shadow 234 in FIG. 2A overlaps with the center 222 of the projection shadow 232, the invention is not so limited. In another embodiment, there can be some offset between the center 224 and the center 222.

The project shadow 232 and the projection shadow 234 are not limited to rectangles. In other embodiments, the conductive pad 202 can have various shapes and therefore the projection shadow 232 of the conductive pad 202 can have various shapes, e.g., polygon, circle, ellipse, irregular shape, etc. Similarly, the top region 218 can have various shapes and therefore the projection shadow 234 of the top region 218 can have various shapes, polygon, circle, ellipse, irregular shape, etc.

In one embodiment, the regions 212, 214-216 and 218 include p-type semiconductor, n-type semiconductor, and p-type semiconductor respectively, and form a PNP BJT. Alternatively, the regions 212, 214-216 and 218 include n-type semiconductor, p-type semiconductor, and n-type semiconductor respectively, and thus form an NPN BJT. In one such embodiment, a base, e.g., the middle region 214-216, of the NPN BJT receives a power voltage, such that the base of the NPN BJT has a substantially constant voltage level that is lower than a voltage level at a collector, e.g., the top region 218, of the NPN BJT and lower than a voltage level at an emitter, e.g., the bottom region 212, of the NPN BJT. The power voltage applied to the base of the NPN BJT can include, but is not limited to, a negative DC power voltage. Thus, the NPN BJT can operate in a cut-off state to block interfering signals that may exist in the bottom region 212.

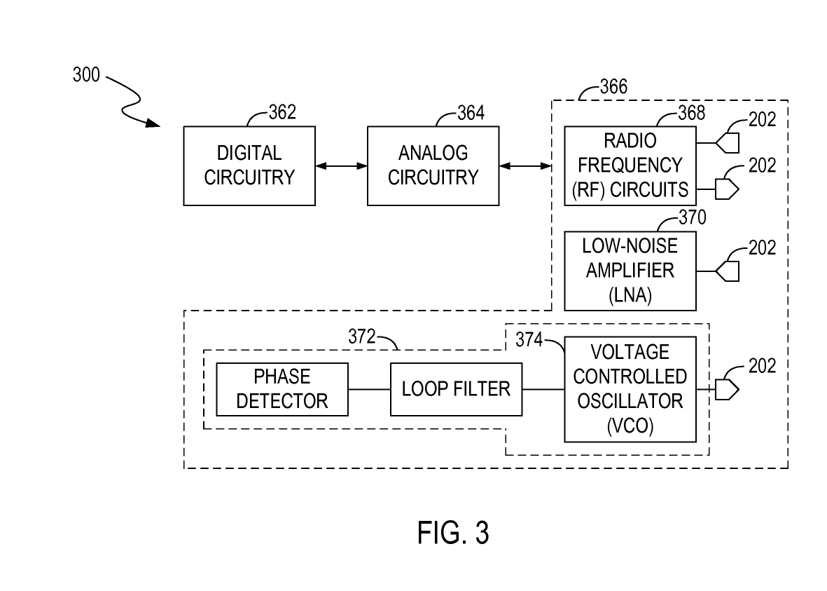

FIG. 3 illustrates a block diagram of an example of an electronic system 300, in accordance with one embodiment of the present invention. In one embodiment, the electronic system 300 is a global positioning system (GPS) system. The electronic system 300 can include digital circuitry 362, e.g., pulse-width modulation circuitry or Inter-Integrated Circuit (I²C) bus circuitry, and analog circuitry 364, e.g., power amplifier circuitry, frequency mixer circuitry, or signal filter circuitry. The electronic system 300 can also include radio frequency (RF) circuitry 366. The RF circuitry 366 can include a low-noise amplifier (LNA) 370 for amplifying an input signal, a phase-locked loop (PLL) 372 for tracking a frequency of an input signal, and other RF circuits 368 for performing other functions.

In one embodiment, the electronic system 300 is integrated on a single chip, e.g., a large-scale integrated (LSI) circuit chip, an ultra-large-scale integrated (USLI) circuit chip, etc. More specifically, the digital circuitry 362, the analog circuitry 364 and the RF circuitry 366 can be fabricated on a wafer 200 shown in FIG. 2A. The RF circuitry 366 includes one or more conductive pads 202 for transferring RF signals, e.g., with frequencies greater than 900 MHz. By way of example, the LNA 370 receives an analog or digital RF signal via a conductive pad 202 to amplify the analog or digital RF signal, and a voltage-controlled oscillator (VCO) 374 in the PLL 372 provides an oscillating signal via a conductive pad 202. The RF circuits 368 can also include one or more conductive pads 202 to receive or output signals. In one embodiment, signals from the digital circuitry 362 or the RF circuitry 366 may become noise signals existing in the substrate of the integrated electronic system 300. Advantageously, the noise signals are prevented from being transferred to the conductive pads 202 of the integrated electronic system 300.

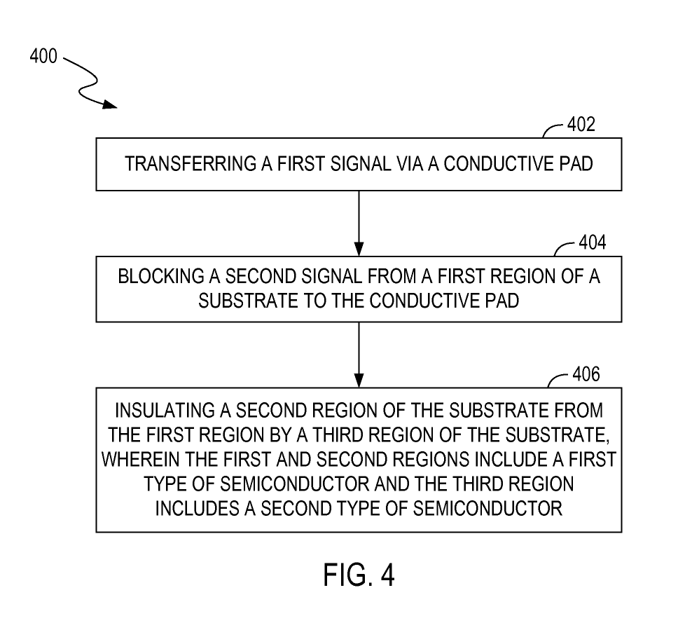

FIG. 4 illustrates a flowchart 400 of examples of operations performed by an integrated circuit, in accordance with one embodiment of the present invention. FIG. 4 is described in combination with FIG. 2A, FIG. 2B and FIG. 3.

In block 402, a circuit, e.g., the LNA 370, the VCO 374, etc., transfers a signal via a conductive pad 202. In block 404, the semiconductor substrate 220 blocks a signal, e.g., an interfering signal caused by the digital circuitry 362 or the RF circuitry 366, from the bottom region 212 to the conductive pad 202. In block 406, the middle region 214-216 insulates the top region 218 from the bottom region 212. The bottom region 212 and the top region 218 include a first type of semiconductor, e.g., p-type semiconductor. The middle region 214-216 includes a second type of semiconductor, e.g., n-type semiconductor. In addition, a projection shadow 234 obtained by perpendicularly projecting the top region 218 onto the bottom surface 230 of the semiconductor substrate 220 overlaps with a projection shadow 232 obtained by perpendicularly projecting the conductive pad 202 onto the bottom surface 230 of the semiconductor substrate 220.

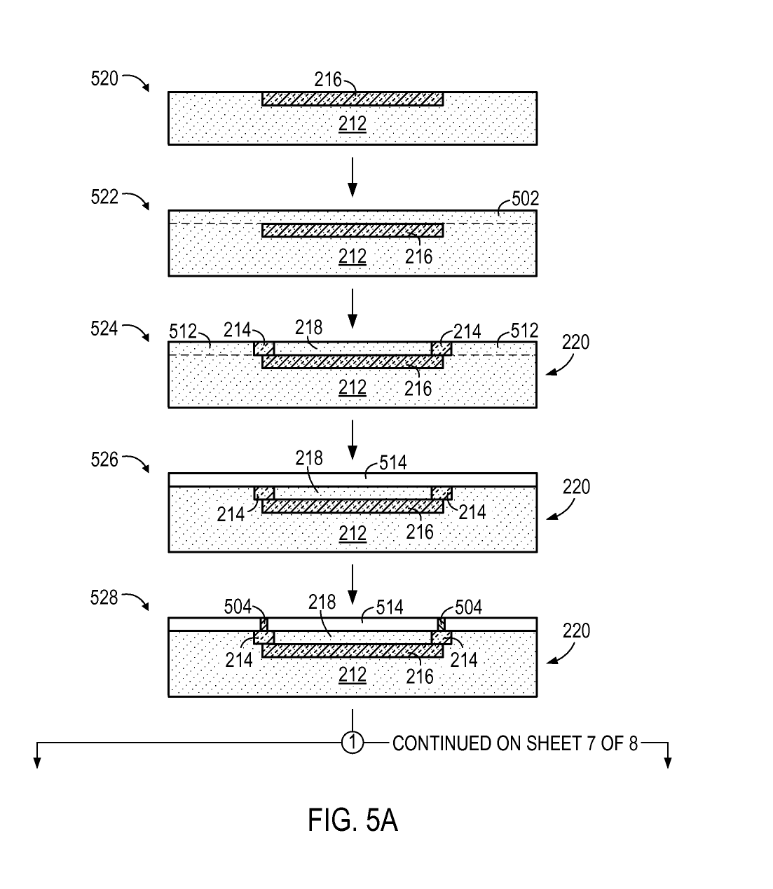

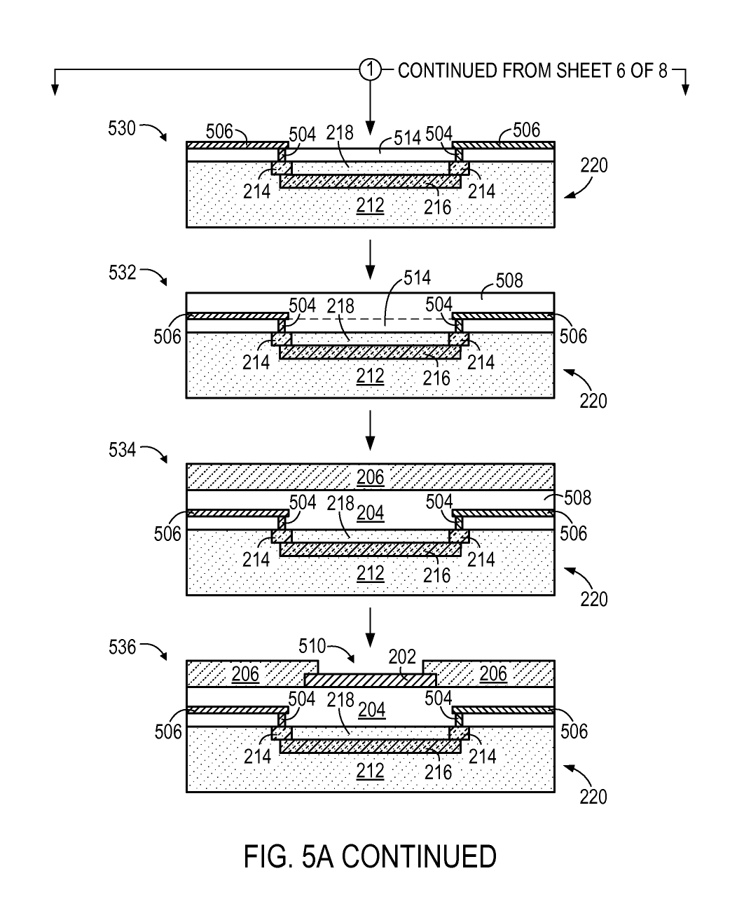

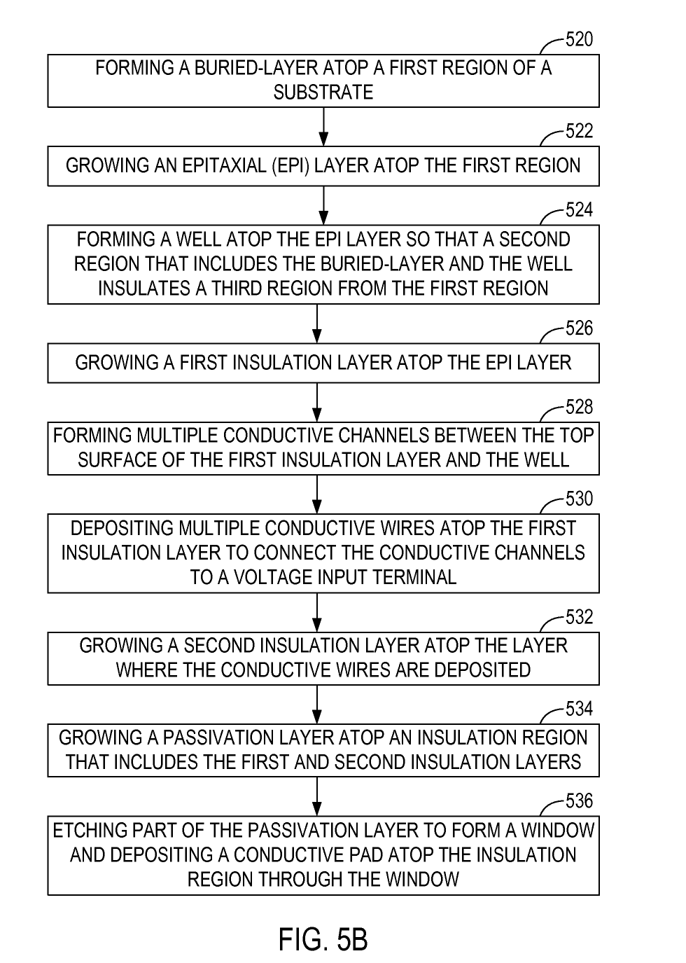

FIG. 5A and FIG. 5B illustrate examples of fabrication steps for an integrated circuit, in accordance with one embodiment of the present invention. Elements that are labeled the same as in FIG. 2A have similar functions. FIG. 5A and FIG. 5B are described in combination with FIG. 2A.

As shown in FIG. 5A and FIG. 5B, at step 520, a buried-layer 216, e.g., an n-type heavily doped buried-layer, is formed atop the bottom region 212 of a substrate. By way of example, the buried-layer 216 can be formed by photomasking and diffusion steps. In one embodiment, the bottom region 212 includes a first type of semiconductor, e.g., p-type semiconductor, and the buried-layer 216 includes a second type of semiconductor, e.g., n-type semiconductor.

At step 522, an epitaxial (epi) layer 502 having the first type of semiconductor is grown atop the bottom region 212. At step 524, a well 214, e.g., an n-type doped well, having the second type of semiconductor is formed atop the epi layer 502, e.g., by photomasking and diffusion steps, so that the middle region 214-216 that includes the buried-layer 216 and the well 214 insulates the top region 218 that is part of the epi layer 502 from the bottom region 212. In one embodiment, part 512 of the epi layer 502 is merged into the bottom region 212. As shown in FIG. 5A, by performing steps 520, 522 and 524, the semiconductor substrate 220 is formed.

At step 526, an insulation layer 514, e.g., a SiO₂ epi layer, is grown atop the epi layer 502 or the semiconductor substrate 220. At step 528, multiple conductive channels 504, e.g., cavities filled with alloy or metal, are formed between the top surface of the insulation layer 514 and the well 214. By way of example, part of the insulation layer 514 is etched to form multiple cavities, and the cavities are filled with alloy or metal. At step 530, multiple conductive wires 506, e.g., alloy or metal wires, are deposited atop the insulation layer 514 to connect the conductive channels 504 to a voltage input terminal (not shown in FIG. 5A). At step 532, an insulation layer 508, e.g., a SiO₂ epi layer, is grown atop the layer where the conductive wires 506 are deposited. In one embodiment, the insulation layers 508 and 514 are merged into an insulation region 204. Conductive channels that include the conductive channels 504 and the conductive wires 506 are formed in the insulation region 204 to connect the middle region 214-216 to the voltage input terminal. In embodiment, the voltage input terminal is used to receive a power voltage 250 shown in FIG. 2B.

At step 534, a passivation layer 206, e.g., a silicon nitride (Si₃N₄) layer, is grown atop the insulation region 204. At step 536, part of the passivation layer 206 is etched to form a window 510, and a conductive pad 202, e.g., a metal pad, is deposited atop the insulation region 204 through the window 510. The insulation region 204 can insulate the conductive pad 202 from the epi layer 502 or the semiconductor substrate 220.

Additionally, a projection shadow obtained by perpendicularly projecting the top region 218 onto a bottom surface of the semiconductor substrate 220 overlaps with a projection shadow obtained by perpendicularly projecting the conductive pad 202 onto the bottom surface of the semiconductor substrate 220. In one such embodiment, the middle region 214-216 is capable of blocking a signal from the bottom region 212 to the conductive pad 202.

While the foregoing description and drawings represent embodiments of the present invention, it will be understood that various additions, modifications and substitutions may be made therein without departing from the spirit and scope of the principles of the present invention as defined in the accompanying claims. One skilled in the art will appreciate that the invention may be used with many modifications of form, structure, arrangement, proportions, materials, elements, and components and otherwise, used in the practice of the invention, which are particularly adapted to specific environments and operative requirements without departing from the principles of the present invention. The presently disclosed embodiments are therefore to be considered in all respects as illustrative and not restrictive, the scope of the invention being indicated by the appended claims and their legal equivalents, and not limited to the foregoing description.

What is claimed is:

1. An integrated circuit comprising:
a conductive pad for transferring a first signal; and
a substrate capable of blocking a second signal from a first region of said substrate to said conductive pad, wherein a second region of said substrate insulates a third region of said substrate from said first region, wherein said first and third regions comprise a first type of semiconductor and said second region comprises a second type of semiconductor, and wherein a first shadow obtained by perpendicularly projecting said third region onto a surface of said substrate overlaps with a second shadow obtained by perpendicularly projecting said conductive pad onto said surface.

2. The integrated circuit as claimed in claim 1, wherein said conductive pad comprises a metal pad.

3. The integrated circuit as claimed in claim 1, further comprising:
an amplifier operable for receiving said first signal via said conductive pad.

4. The integrated circuit as claimed in claim 1, further comprising:
an oscillator operable for providing said first signal via said conductive pad.

5. The integrated circuit as claimed in claim 1, wherein said first signal has a frequency that is greater than 900 MHz.

6. The integrated circuit as claimed in claim 1, wherein said second signal comprises an interfering signal caused by digital circuitry of said integrated circuit.

7. The integrated circuit as claimed in claim 1, wherein said second signal comprises an interfering signal caused by radio-frequency circuitry of said integrated circuit.

8. The integrated circuit as claimed in claim 1, wherein said first type of semiconductor comprises p-type semiconductor and said second type of semiconductor comprises n-type semiconductor.

9. The integrated circuit as claimed in claim 8, wherein said second region has a substantially constant voltage level that is higher than a voltage level at said first region and higher than a voltage level at said third region.

10. The integrated circuit as claimed in claim 1, wherein said first, second and third regions form a transistor.

11. A method for transferring a first signal, said method comprising:
transferring said first signal via a conductive pad;
blocking a second signal from a first region of a substrate to said conductive pad; and
insulating a second region of said substrate from said first region by a third region of said substrate;
wherein said first and second regions comprise a first type of semiconductor and said third region comprises a second type of semiconductor, and wherein a first shadow obtained by perpendicularly projecting said second region onto a surface of said substrate overlaps with a second shadow obtained by perpendicularly projecting said conductive pad onto said surface.

12. The method as claimed in claim 11, wherein said first signal has a frequency that is greater than 900 MHz.

13. The method as claimed in claim 11, wherein said first type of semiconductor comprises p-type semiconductor and said second type of semiconductor comprises n-type semiconductor.

14. The method as claimed in claim 13, further comprising:
controlling a voltage level at said third region to be substantially constant and higher than a voltage level at said first region and higher than a voltage level at said second region.

15. A method for fabricating an integrated circuit, said method comprising:
forming a buried-layer atop a first region of a substrate;
forming a well atop an epitaxial (epi) layer grown atop said first region so that a second region that includes said buried-layer and said well insulates a third region from said first region; and
depositing a conductive pad atop an epi region grown atop said epi layer,
wherein said first and third regions comprise a first type of semiconductor and said second region comprises a second type of semiconductor, and wherein a first shadow obtained by perpendicularly projecting said third region onto a surface of said substrate overlaps with a second shadow obtained by perpendicularly projecting said conductive pad onto said surface.

16. The method as claimed in claim 15, further comprising:
forming a conductive channel in said epi region to connect said second region to a voltage input terminal.

17. The method as claimed in claim 15, wherein said third region is part of said epi layer.

18. The method as claimed in claim 15, wherein said epi region comprises oxide to insulate said conductive pad from said substrate.

19. The method as claimed in claim 15, wherein said first type of semiconductor comprises p-type semiconductor and said second type of semiconductor comprises n-type semiconductor.
